(19) United States
(12) Patent Application Publication
(10) Pub. No.: US 2012/0134211 A1
(43) Pub. Date: May 31, 2012

(54) MEMORY SYSTEM

(75) Inventors: Jin KASHIWAGI, Kanagawa-ken (JP); Shirou Fujita, Kanagawa-ken (JP); Toshifumi Watanabe, Kanagawa-ken (JP)

(73) Assignee: KABUSHIKI KAISHA TOSHIBA, Minato-ku (JP)

(21) Appl. No.: 13/306,636

(22) Filed: Nov. 29, 2011

(30) Foreign Application Priority Data
Nov. 30, 2010 (JP) P2010-267828

(51) Int. Cl. G11C 16/26

(52) U.S. Cl. 365/185.11

(57) ABSTRACT

A memory system includes: a plurality of banks each including a memory cell array and a sense amplifier; a buffer circuit electrically connected to the plurality of banks; a switch circuit configured to switch on and off an electrical connection between the buffer circuit and each of the plurality of banks an interface electrically connected to the buffer circuit; and a controller configured to control the plurality of banks, the buffer circuit, the switch circuit and the interface, wherein for reading data held in the memory cell array by outputting the data to the interface in 5 clock cycles, the controller is configured to control the switch circuit in order that the switch circuit electrically connects a selected one of the banks to the buffer circuit upon the lapse of 1.5 clock cycles after a clock is inputted into the selected bank.

### CROSS-REFERENCE TO RELATED APPLICATIONS

This application is based upon and claims the benefit of priority from the prior Japanese Patent Application No. 2010-267828 filed Nov. 30, 2010, the entire contents of which are incorporated herein by reference.

### FIELD

Embodiments described herein relate generally to memory system, and is applied to, for example, a semiconductor memory system including multiple types of memories integrated in a single chip, or the like.

### BACKGROUND

An example of a semiconductor memory system including multiple types of memories integrated in a single chip is a semiconductor memory system including a NAND flash memory (memory unit) and a SRAM (Static Random Access Memory) integrated in a single chip.

### BRIEF DESCRIPTION OF THE DRAWINGS

FIG. 1 is a block diagram showing a memory system of a first embodiment.

FIG. 2 is a circuit diagram showing a memory cell array of the first embodiment.

FIG. 3 is a block diagram showing a connecting relationship among a data RAM, a burst buffer and an interface in the memory system of the first embodiment.

FIG. 4 is a timing chart showing timings at which the memory system of the first embodiment reads data from banks.

### DETAILED DESCRIPTION

In general, according to one embodiment, a memory system includes: a plurality of banks each including a memory cell array and a sense amplifier; a buffer circuit electrically connected to the plurality of banks; a switch circuit configured to switch on and off an electrical connection between the buffer circuit and each of the plurality of banks; an interface electrically connected to the buffer circuit; and a controller configured to control the plurality of banks, the buffer circuit, the switch circuit and the interface, wherein for reading data held in the memory cell array by outputting the data to the interface in 5 clock cycles, the controller is configured to control the switch circuit in order that the switch circuit electrically connects a selected one of the banks to the buffer circuit upon the lapse of 1.5 clock cycles after a clock is inputted into the selected bank.

### First Embodiment

Next, descriptions will be provided for a first embodiment by referring to the drawings. For the descriptions, the same or similar portions will be denoted by the same or similar reference signs throughout the drawings. In addition, dimensional ratios inferred from the drawings are not limited to that shown in the drawings.

### [Configuration of Memory System]

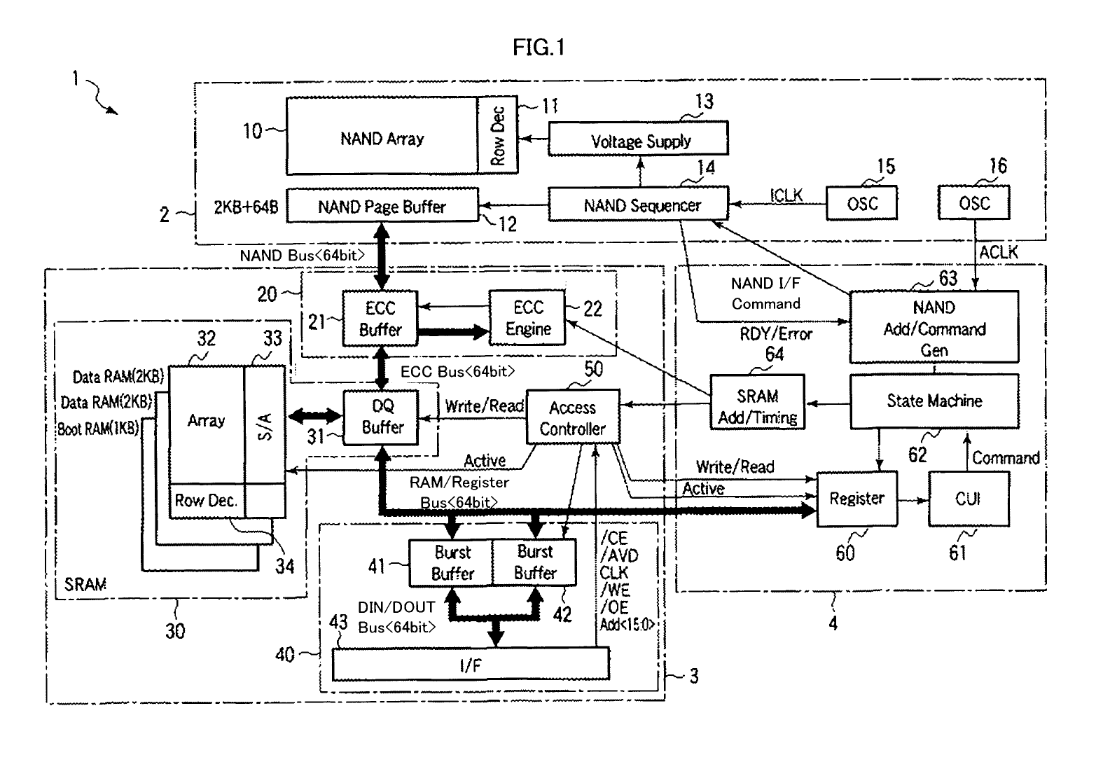

Descriptions will be provided for a memory system of the first embodiment by use of a block diagram shown in FIG. 1. As shown in FIG. 1, a memory system 1 includes a NAND flash memory 2, a RAM unit 3 and a controller unit 4. For example, in the memory system 1, the NAND flash memory 2, the RAM unit 3 and the controller unit 4 are integrated into a single chip while formed on the same semiconductor substrate.

### <NAND Flash Memory>

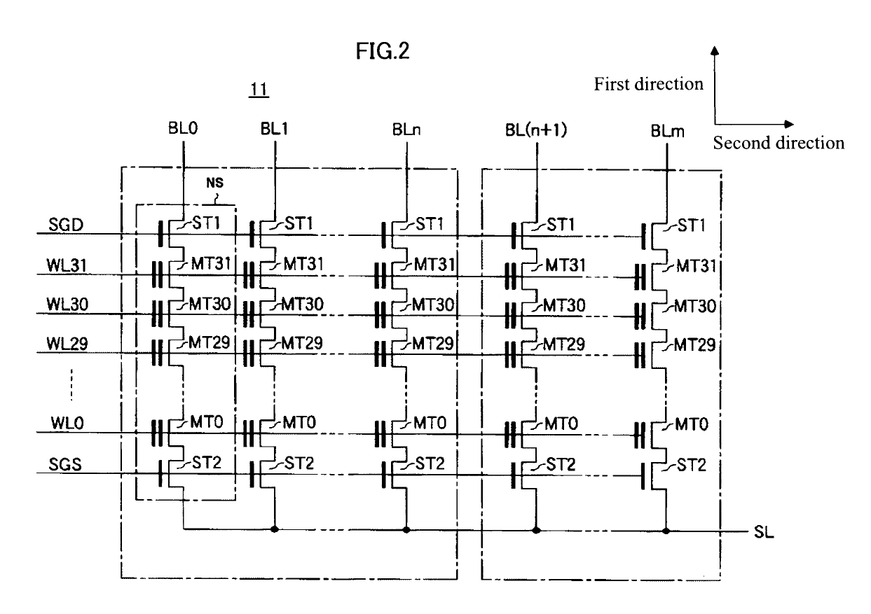

To begin with, the NAND flash memory 2 will be described by use of FIG. 1 and a circuit diagram shown in FIG. 2.

The NAND flash memory 2 functions as a main storage unit of the memory system 1. As shown in FIG. 1, the NAND flash memory 2 includes a NAND memory cell array 10, a row decoder 11, a page buffer 12, a column decoder (whose illustration is omitted), a voltage generating circuit 13, a sequencer (NAND Sequencer in FIG. 1) 14, and oscillators 15, 16.

### <<Memory Cell Array>>

As shown in FIG. 2, the memory cell array 10 includes multiple NAND strings NS which are arranged in a matrix. In addition, the memory cell array 10 includes: a first area in which regular data (user data) is stored; and a second area used as a spare area for the first area, in which data is stored. For example, the parity to be used for error correction is stored in the second area.

Multiple bit lines BL0 to BLm (m: a natural number) are arranged, extending in a direction (first direction) in which the NAND strings NS extend, over the respective NAND strings NS on the semiconductor substrate (whose illustration is omitted). Each of the bit lines BL0 to BLm is electrically connected to end portions of the corresponding NAND string NS.

On the other hand, multiple word lines WL0 to WL31 extend in a direction (second direction) orthogonal to the first direction in which the NAND strings NS extend, and are arranged one after another at predetermined intervals in the first direction. In this respect, the first direction is also a direction in which an active region extends.

Multiple selection gate lines SGS, SGD are arranged outside, and in parallel to, the word lines WL0, WL31 with the multiple word lines WL0 to WL31 interposed in between.

Each NAND string NS is formed from multiple memory cells MT0 to MT31, as well as first and second selection gate transistors ST1, ST2. Each memory cell MT has a stacked gate structure which includes: a charge storage layer formed above the semiconductor substrate with a gate insulator in between; and a control gate formed above the charge storage layer with an inter-gate insulator. Incidentally, the number of memory cells MT included in each NAND string NS is not limited to 32. Any one of 8, 16, 34, 128, 256 and the like is an acceptable number. No specific restriction is imposed on the number of memory cells MT in each NAND string NS. Furthermore, each memory cell transistor MT may have a MONOS (Metal Oxide Nitride Oxide Silicon) structure using a technique of trapping electrons in a nitride film, instead of the stacked gate structure.

In each NAND string NS, the multiple memory cells MT0 to MT31 are formed in locations corresponding to intersections between the word lines WL and the corresponding bit line BL, and are connected one to another in series in the direction in which the active region (whose illustration is omitted) extends.

Moreover, in each NAND string NS, as shown in FIG. 2, the first selection gate transistor ST1, first in a series of transistors, connected to the bit line BL is connected to the memory cell MT31 in series, while the second selection gate transistor ST2 closest to a source line SL is connected to the memory cell MT0 in series. The source line SL is commonly connected to each NAND string NS.

As shown in FIG. 2, control gates of the corresponding memory cells MT, arranged in each row extending in the second direction, among the respective NAND strings NS are connected to a corresponding common word line WL. In addition, control gates of the corresponding first selection gate transistors ST1 arranged in the second direction are connected to the first selection gate line SGD. Control gates of the corresponding second selection gate transistors ST2 arranged in the second direction are connected to the second selection gate line SGS.

The multiple NAND strings NS are formed in a matrix inside the memory cell array 10. Each set of memory cells MT, sharing one word line WL, among the respective NAND strings NS constitutes a page which is a unit of data reading or a unit of data writing. In addition, a set of NAND strings NS sharing the word lines WL constitutes a block which is a data erase unit.

### <<Page Buffer>>

The page buffer 12 is capable of holding a page of data. During data write operation, the page buffer 12 temporarily holds data given to the page buffer 12 by the RAM unit 3, and writes the data to the memory cell array 10. On the other hand, during data read operation, the page buffer 12 temporarily holds data read from the memory cell array 10, and transfers the data to the RAM unit 3.

A region in the page buffer 12 is used to hold main data, and the remaining region in the page buffer 12 is used to hold the parity and the like.

### <<Row Decoder and Column Decoder>>

The row decoder 11 selects a desired word line(s) WL in the memory cell array 10. In addition, the column decoder (whose illustration is omitted) selects a desired column(s), namely, a desired bit line(s) BL in the memory cell array 10.

### <<Voltage Generating Circuit>>

The voltage generating circuit 13 generates a voltage needed for data write operation, data read operation and data erase operation by raising or dropping a voltage given from the outside. Thus, the voltage generating circuit 13 supplies the generated voltage to the row decoder 11, for example. Hence, the voltage generated by the voltage generating circuit 13 is applied to the desired word line(s) WL.

### <<Sequencer>>

The sequencer 14 controls the operation of the NAND flash memory 2 as a whole. Once receiving a NAND interface command (denoted by reference sign NAND I/F Command in FIG. 1) from the controller unit 4, the sequencer 14 executes a sequence corresponding to the NAND interface command (for example, a sequence for executing data programming). In accordance with this sequence, the sequencer 14 controls the operation of the page buffer 12, the operation of the voltage generating circuit 13, and the like. The sequencer 14 operates in synchronism with an internal clock ICLK transferred from the oscillator 15, which will be described later.

### <<Oscillator>>

The oscillator 15 (clock generator) generates the internal clock ICLK. The oscillator 15 transfers the generated internal clock ICLK to the sequencer 14.

The oscillator 16 (clock generator) generates the other internal clock ACLK. The oscillator 16 transfers the generated internal clock ACLK to the controller unit 4 and the like. The internal clock ACLK is a clock serving as a reference with which the controller unit 4 and the like operate in synchronism.

### <RAM Unit>

As shown in FIG. 1, the RAM unit 3 includes an ECC portion 20, a SRAM 30, an interface portion (an I/F portion) 40, and an access controller 50.

During the data read operation, the ECC portion 20 detects and corrects an error(s) concerning the data read from the NAND memory cell array 10. On the other hand, during the data write operation, the ECC portion 20 generates the parity concerning data to be programmed.

The ECC portion 20 includes an ECC buffer 21 and an ECC engine 22. In this respect, the ECC buffer 21 is connected to the page buffer 12 via a NAND bus. The ECC buffer 21 is connected to the SRAM 30 via an ECC bus.

During the data read operation, the ECC buffer 21 holds data transferred from the page buffer 12, and transmits ECC-processed data (error-corrected data in the case of data loading) to the SRAM 30. On the other hand, during the data write operation, the ECC buffer 21 holds data transferred from the SRAM 30, and transfers the data transferred from the SRAM 30 and the parity to the page buffer 12.

The ECC engine 22 applies an ECC process to data held in the ECC buffer 21. The ECC engine 22 employs a one-bit correction method using, for example, Hamming codes. In addition, the ECC engine 22 uses a minimum amount of parity data for its error correction.

### <<SRAM>>

As shown in FIG. 1, the SRAM 30 includes a DQ buffer 31, multiple data RAMs and a boot RAM. Each of the data RAMs and the boot RAM includes a memory cell array 32, a sense amplifier 33 and a row decoder 34. The capacity of each data RAM is 2K bytes, for example. The capacity of the boot RAM is 1K bytes, for example.

The memory cell array 32 of each of the multiple data RAMs includes multiple SRAM cells capable of holding data. The SRAM cells are connected to the word lines and the bit lines. Like the memory cell array 10, each SRAM memory cell array 32 includes: an area for holding main data; and an area for holding parity.

The sense amplifier 33 of each Data RAM senses and amplifies data read to bit lines from SRAM cells. The row decoder 34 selects a word line(s) in the memory cell array 32 of the same Data RAM.

The boot RAM temporarily holds a boot code for activating the memory system 1, for example. The DQ buffer 31 temporarily holds data when the data is written into the data RAMs, or when the data is read from the data RAMs.

As shown in FIG. 1, the DQ buffer 31 is electrically connected to the ECC buffer 21 via an ECC bus. As a result, data can be transferred between the DQ buffer 31 and the ECC buffer 21. In addition, use of the RAM/register bus enables data to be transmitted between the DQ buffer 31 and the burst buffers, which will be described later. The DQ buffer 31 includes: a region in which to hold main data; and a region in which to hold the parity and the like.

### <<Interface Unit>>

The interface unit 40 includes the burst buffers (buffer circuits) 41, 42, and an interface (an I/F shown in FIG. 1) 43.

The burst buffers 41, 42 are electrically connected to the DQ buffer 31 and the controller unit 4 via the RAM/Register bus. As a result, data can be transferred among the DQ buffer 31, the controller unit 4 and each of the burst buffers 41, 42.

The burst buffers 41, 42 are electrically connected to the interface 43 via a DIN/OUT bus. As a result, data can be transferred between the interface 43 and each of the burst buffers 41, 42. The burst buffers 41, 42 temporarily hold data given to the burst buffers 41, 42 from a host apparatus via the interface 43, or data given to the burst buffers 41, 42 from the DQ buffer 31.

The burst buffer 41 is used to write data when the data is inputted into the burst buffer 41 from the interface 43. The burst buffer 42 is used to output data to the interface 43 when the data is read. The burst buffers 41, 42 each have a 32-bit capacity, for example.

The interface 43 is capable of being connected to the host apparatus outside the memory system 1. The interface 43 controls the input and output of various signals, such as data, control signals and addresses, to and from the host apparatus.

Examples of the signals include: a chip enable signal /CE for enabling the entire memory system 1; an address valid signal /AVD for latching an address; a clock CLK for a burst read; a write enable signal /WE for enabling a write operation; and an output enable signal /OE for enabling the output of data to the outside.

The interface 43 is electrically connected to the burst buffer 41, 42 via the DIN/OUT bus. The interface 43 transfers control signals from the host apparatus concerning a data read request, a load request, a write request and the like to an access controller 50. For a data read operation, the interface 43 outputs data in the burst buffer 42 to the host apparatus. For a data write operation, the interface 43 transfers data, which is given to the interface 43 from the host apparatus, to the burst buffer 41.

### <<Access Controller>>

The access controller 50 receives a control signal and an address from the interface 43. Thereby, the access controller 50 controls the SRAM 30 and the control unit 4 in order for an operation, which satisfies a request of the host apparatus, to be executed.

Specifically, in response to a request from the host apparatus, the access controller 50 puts either the SRAM 30 or a register 60 inside the controller unit 4 in an active state. Subsequently, the access controller 50 issues a write command or a read command of data (denoted by reference sign Write/Read in FIG. 1) to the SRAM 30, or a write command or a read command (denoted by reference sign Write/Read in FIG. 1; hereinafter referred to as a “register write command” or a “register read command”) to the register 60. As a result, the SRAM 30 or the controller unit 4 commence operation.

The access controller 50 has burst buffer control circuits (whose illustration is omitted) for controlling the respective burst buffers 41, 42. The access controller 50 causes selected address signals and clocks to be inputted into the burst buffers 41, 42.

### <<Configuration Between SRAM 30 and Interface Portion 40>>

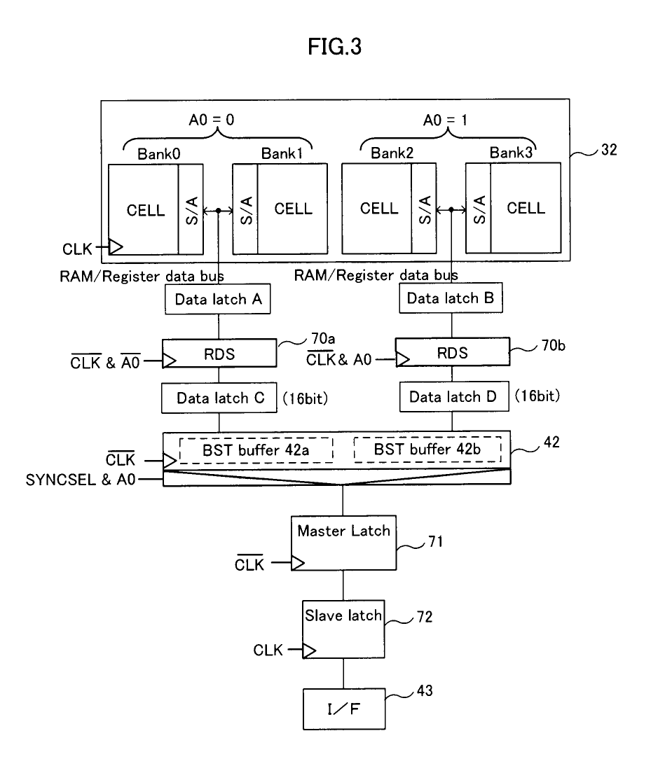

Next, descriptions will be provided for a configuration between the SRAM 30 and the interface portion 40 by use of an example shown in FIG. 3. Incidentally, the DQ buffer 31 shown in FIG. 1 is omitted from FIG. 3. Like the DQ buffer 31, the burst buffer 41 is omitted from FIG. 3.

Each memory cell array 32 shown in FIG. 1 includes multiple banks (bank 0 to bank 3 in FIG. 3) each including SRAM cells. The SRAM cell in each bank is connected to the sense amplifier circuit (denoted by reference sign S/A in FIG. 3). An address is set for each bank. For example, as shown in FIG. 3, an address “A0=0” is set for the bank 0 and the bank 1, while an address “A0=1” is set for the bank 2 and the bank 3. A clock is inputted into each of the banks, and data (16-bit data) is outputted from the memory cell array 32. When a clock is inputted into one of the two adjacent banks, another clock delayed by one clock cycle is inputted into the other bank. For example, the bank 1 receives a clock delayed by one cycle from a clock inputted into the bank 0.

As shown in FIG. 3, data latches A, B are circuits in which to store data outputted from the memory cell array 32 to a RAM/Register data bus. Furthermore, a read data switch (hereinafter abbreviated as “RDS”) 70a has a function of switching on and off the connection of the data latch A to a data latch C, while a read data switch RDS 70b has a function of switching on and off the connection of the data latch B to a data latch D.

A selected address signal for selecting either the read data switch RDS 70a or the read data switch RDS 70b, and a clock for controlling the switching on and off of the connections are inputted into the read data switch RDS 70a, 70b. The selected address signal and the clock are controlled by the access controller 50. This clock is an inverted clock which is the inverse of the clock inputted into the banks (denoted by reference sign (CLK with a bar on it) in FIG. 3).

The data latches C, D are circuits for storing data outputted from the data latches A, B by the read data switches RDS 70a, 70b, respectively. The data latches C, D are connected to the burst buffer 42.

Thereby, the burst buffer 42 is electrically connected to the banks 0 to 3 in the memory cell array 32 via the RAM/register data bus and the like. In this respect, to “be electrically connected to” is not limited to “be directly connected to” (in the above-described case, “the burst buffer 42 is directly connected to the banks 0 to 3”), but may include “be capable of sending and receiving an electric signal.”

The burst buffer 42 includes burst buffers 42a, 42b. The burst buffer 42a is a buffer for holding data inputted into the burst buffer 42a from the data latch C, and has a 16-bit capacity, for example. The burst buffer 42b is a buffer for holding data inputted into the burst buffer 42b from the data latch D, and has a 16-bit capacity, for example.

An inverted clock and a selected data signal for selecting either data held in the burst buffer 42a or data held in the burst buffer 42b are inputted into the burst buffer 42. Thus, the burst buffer 42 is controlled by the access controller 50. Thereby, out of the data (32 bits in length) held in the burst buffer 42, the 16-bit data having been inputted into the burst buffer 42 from the data latch C is selected, for example.

The inverted clock inputted into the burst buffer 42 causes the selected data to be outputted to a master latch circuit 71.

Once an inverted clock is inputted into the master latch circuit 71, the data held in the master latch circuit 71 is outputted to a slave latch circuit 72. Furthermore, once a clock is inputted into the slave latch circuit 72, the data held in the slave latch circuit 72 is outputted to the interface 43.

Thereby, the interface 43 is electrically connected to the burst buffer 42 via the master latch circuit 71, the slave latch circuit 72.

### <Controller Unit>

As shown in FIG. 1, the controller unit 4 includes the register 60, a CUI (Command User Interface) 61, a state machine 62, an address/command generator circuit 63 and an address/timing generator circuit 64.

### <<Register>>

The register 60 sets up an operational status of a function. The register 60 allocates part of an external address space to this end. Thereby, the external host apparatus reads or writes either an address signal or a control signal, such as a command, from and to the allocated part of the external address space of the register 60 via the interface 43.

### <<CUI>>

Once the address signal or the control signal such as a command is written into the predetermined part of the external address space of the register 60, the CUI 61 recognizes that a function execution command is given to the CUI 61, and issues an internal command signal.

### <<State Machine>>

Upon reception of a command issued from the address/command generator circuit 63 which will be described later or the internal command signal from the CUI 61, the state machine 62 controls an internal sequence operation depending on what type the command is of.

### <<Address/Command Generator Circuit>>

The address/command generator circuit 63 plays a roll of generating an address signal and a control signal such as a command to the NAND flash memory 2 depending on the necessity during the internal sequence operation.

### <<Address/Timing Generator Circuit>>

The address/timing generator circuit 64 generates an address and a control signal, such as a signal representing timing, for controlling the SRAM 30 depending on the necessity during the internal sequence operation.

### [How the Memory System Operates]

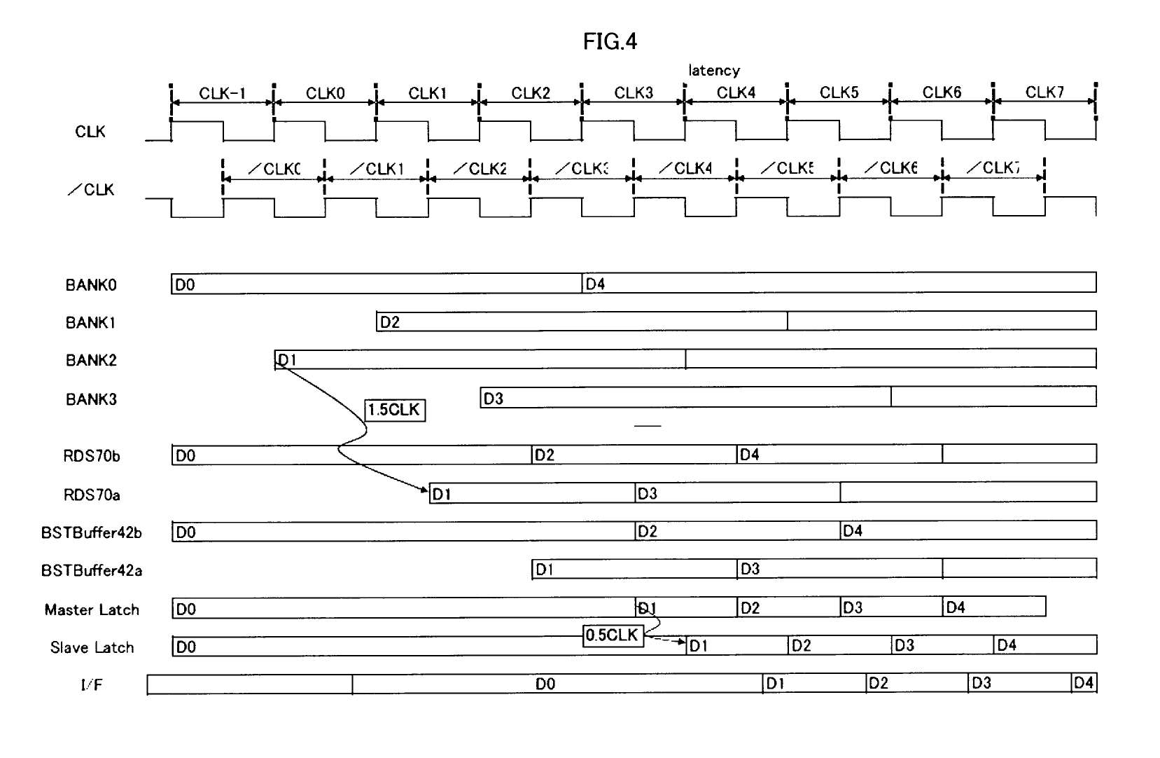

Next, using an example in which the memory system of the first embodiment operates until the memory system sequentially outputs data 1 to 4 held in the banks 0 to 3 to the external host apparatus, descriptions will be provided for how the memory system operates by use of the block diagram shown in FIG. 3 and a timing chart shown in FIG. 4.

For the sake of explanatory convenience, let us assume that: data 1, data 2, data 3 and data 4 are held in the bank 2, the bank 1, the bank 3 and the bank 0, respectively; and a latency for reading data from each bank to the interface 43 is 4 clocks long. The following descriptions assume that a clock frequency is 104 Mhz, for example.

First of all, in step S1, by use of the access controller 50, a process of inputting a clock into the bank 0, and a process of fetching a control signal and an address from the interface 43 are performed (operation at a clock CLK-1).

In step S2, a clock is inputted into the bank 2 by use of the access controller 50. Once a clock CLK0 rises (the clock CLK0 turns into an “H” state), the data 1 (which is denoted by reference sign D1 in FIG. 4, and is 16 bits long) is transferred to the data latch B via the sense amplifier of the bank 2 (operation at the clock CLK0). After a desired length of time passes, this data 1 is held in the data latch B.

In step 3, a clock is inputted into the bank 1 by the use of the access controller 50. Once a clock CLK1 rises, the data 2 (which is denoted by reference sign D2 in FIG. 4, and is 16 bits long) is transferred to the data latch A via the sense amplifier of the bank 1 (operation at the clock CLK1). After a desired length of time passes, this data 2 is held in the data latch A.

In step S4, an inverted clock is inputted into the read data switch RDS 70b, which is selected by a selected address signal, by use of the access controller 50. Once an inverted clock /CLK2 rises (the clock CLK1 falls, i.e., turns from the “H” state to a “L” state), the read data switch RDS 70b connects the data latch B and the data latch D together. Thereby, the data 1 is held in the data latch D. In other words, the step S4 is performed once 1.5 clock cycles pass after the step S2.

In step S5, a clock is inputted into the bank 3. Once a clock CLK2 rises, the data 3 (which is denoted by reference sign D3 in FIG. 4, and are 16 bits long) is transferred to the data latch B (operation at the clock CLK2), like in step S2. After a desired length of time passes, this data 3 is held in the data latch B to update the data 1 in the data latch B.

In step S6, by use of the access controller 50, an inverted clock is inputted into the read data switch RDS 70a, which is selected by a selected address signal, and the burst buffer 42. Once an inverted clock /CLK3 rises, the read data switch RDS 70a connects the data latch A and the data latch C together. Thereby, the data 2 is held in the data latch C.

In addition, the data 1 selected by a selected data signal inputted into the burst buffer 42 is transferred to the master latch circuit 71.

In step 7, a clock is inputted into the bank 0 by use of the use of the access controller 50, like in step S3. Once a clock CLK3 rises, the data 4 (which is denoted by reference sign D4 in FIG. 4, and is 16 bits long) is transferred to and held in the data latch A (operation at the clock CLK3) to update the data 2 in the data latch A.

In step S8, an inverted clock is inputted into the read data switch RDS 70b selected by a selected address signal, as well as the burst buffer 42 and the master latch circuit 71, like in step S4. Once an inverted clock /CLK4 rises, the master latch circuit 71 is updated to receive the data 1, and transfers the data 1 to the slave latch circuit 72.

Furthermore, the data 2 selected by a selected data signal inputted into the burst buffer 42 is transferred to the master latch circuit 71.

Furthermore, the read data switch RDS 70b connects the data latch B and the data latch D together. Thereby, the data 3 is held in the data latch D.

In step S9, a clock is inputted into the slave circuit 72 by use of the access controller 50. Once a clock CLK4 rises, the slave latch circuit 72 is updated to receive the data 1, and outputs the data 1 to the interface 43.

In step S10, an inverted clock is inputted into the read data switch RDS 70a selected by a selected address signal, as well as the burst buffer 42 and the master latch circuit 71. Once an inverted clock /CLK5 rises, the data 2 held in the master latch circuit 71 is transferred to the slave latch circuit 72.

In addition, the data 3 selected by a selected data signal inputted into the burst buffer 42 is transferred to the master latch circuit 71. Furthermore, the read data switch RDS 70a connects the data latch A and the data latch C together. Thereby, the data 4 is held in the data latch D.

In step S11, a clock is inputted into the slave circuit 72 by use of the access controller 50. Once a clock CLK5 rises, the slave latch circuit 72 is updated to receive the data 2, and outputs the data 2 to the interface 43.

In step S12, once the use of the access controller 50 causes an inverted clock /CLK6 to rise, the master latch circuit 71 is updated to receive the data 3, and transfers the data 3 to the slave latch circuit 72. In addition, the data 4 selected by a selected data signal inputted into the burst buffer 42 is transferred to the master latch circuit 71.

In step 13, once a clock CLK6 rises, the slave latch circuit 72 is updated to receive the data 3, and outputs the data 3 to the interface 43.

In step 14, once an inverted clock CLK7 rises, the master latch circuit 71 is updated to receive the data 4, and outputs the data 4 to the slave latch circuit 72.

In step 15, once a clock CLK7 rises, the slave latch circuit 72 is updated to receive the data 4, and outputs the data 4 to the interface 43.

### [Effects of First Embodiment]

Because of the foregoing operation, the embodiment can provide a memory system capable of reading data at high speed. Detailed descriptions will be provided below.

With regard to the memory system of the embodiment, in a case where, for example, the frequency is 104 Mhz, a core access time taken to perform a read operation on each of the banks and to read data from the bank to the data latch A or B is 1.5 clock cycles, and a time taken to transfer the data from the master latch circuit 71 to the slave latch circuit 72 is 0.5 clock cycles.

On the other hand, with regard to a memory system of a comparative example, a core access time taken to perform a read operation on each of the banks and to read data from the bank to the data latch A or B is one clock cycle, and a time taken to transfer the data from the master latch circuit 71 to the slave latch circuit 72 is one clock cycle.

It may be conceived that the high speed reading of data from each of the banks can be achieved by increasing the frequency of clocks to be inputted into the banks and the like. However, the increase in the frequency makes the core access time likely to exceed the one clock cycle, because a certain time length is still needed as the core access time taken to perform a read operation on each of the banks and to read data from the bank to the data latch A or B. For this reason, the memory system of the comparative example may be unable to transfer data from each of the banks to the data latch A or B in one clock cycle.

The embodiment, however, makes it possible to transfer data from each of the banks to the data latch A or B correctly in the case where, for example, the frequency is 104 Mhz, because the core access time taken to perform a read operation on each of the banks and to read data from the bank to the data latch A or B is set at 1.5 clock cycles.

For this reason, the memory system of the embodiment is capable of reading data at higher speed and more correctly than the memory system of the comparative example.

Furthermore, the memory system of the embodiment is capable of reading data without an increase in latency, because the time taken to transfer data from the master latch circuit 71 to the slave latch circuit 72 is set at the 0.5 clock cycles.

Although the time taken to transfer data from the master latch circuit 71 to the slave latch circuit 72 is set at 0.5 clock cycles, the memory system of the embodiment is not limited to this case. A time taken to transfer data to the master latch circuit 71 may be set at 0.5 clock cycles.

In a case where the time taken to transfer data to the master latch circuit 71 is set at 0.5 clock cycles, the process of transferring data to the master latch circuit 71 and the process of selecting data by use of a selected data signal inputted into the burst buffer 42 need be carried out in parallel. In the embodiment, however, no process needs to be carried out in parallel to the process of transferring data from the master latch circuit 71 to the slave latch circuit 72.

For this reason, the memory system of the embodiment is capable of reading data at higher speed than in the case where the time taken to transfer data to the master latch circuit 71 is set at the 0.5 clock cycles.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a plurality of banks each including a memory cell array and a sense amplifier;
a buffer circuit electrically connected to the plurality of banks;
a switch circuit configured to switch on and off an electrical connection between the buffer circuit and each of the plurality of banks;
an interface electrically connected to the buffer circuit; and
a controller configured to control the plurality of banks, the buffer circuit, the switch circuit and the interface, wherein
for reading data held in the memory cell array by outputting the data to the interface in 5 clock cycles, the controller is configured to control the switch circuit in order that the switch circuit electrically connects a selected one of the banks to the buffer circuit upon the lapse of 1.5 clock cycles after a clock is inputted into the selected bank.

2. The memory system of claim 1, wherein
the controller is configured to input an inverted clock, which is an inverse of the clock, into the switch circuit.

3. The memory system of claim 2, wherein
the controller is configured to input the inverted clock into the buffer circuit upon the lapse of one clock cycle after the inverted clock is inputted into the switch circuit.

4. The memory system of claim 2, further comprising:
a master latch circuit electrically connected to the buffer circuit;
a slave latch circuit connected between the master latch circuit and the interface, wherein
for reading the data held in the memory cell array by outputting the data to the interface in the 5 clock cycles, the controller is configured to input a second clock into the slave latch circuit upon the lapse of 0.5 clock cycles after a first clock is inputted into the master latch circuit.

5. The memory system of claim 3, further comprising:
a master latch circuit electrically connected to the buffer circuit;
a slave latch circuit connected between the master latch circuit and the interface, wherein
for reading the data held in the memory cell array by outputting the data to the interface in the 5 clock cycles, the controller is configured to input a second clock into the slave latch circuit upon the lapse of 0.5 clock cycles after a first clock is inputted into the master latch circuit.

6. The memory system of claim 4, wherein
the first clock is the inverted clock.

7. The memory system of claim 5, wherein
the first clock is the inverted clock.

8. The memory system of claim 6, wherein
for reading data held in the memory cell array by outputting the data to the interface in the 5 clock cycles, the controller is configured to input the inverted clock into the master latch circuit upon the lapse of one clock cycle after the inverted clock is inputted into the buffer circuit.

9. The memory system of claim 7, wherein
for reading data held in the memory cell array by outputting the data to the interface in the 5 clock cycles, the controller is configured to input the inverted clock into the master latch circuit upon the lapse of one clock cycle after the inverted clock is inputted into the buffer circuit.

10. The memory system of claim 1, wherein
the plurality of banks include a first bank and a second bank,
the switch circuit is commonly electrically connected to the first bank and the second bank, and
for reading data held in the memory cell array by outputting the data to the interface, the controller is configured to select the first bank and the second bank alternately, and thereby to input the clock into the first bank and the second bank in turn.

11. The memory system of claim 4, wherein
the plurality of banks include a first bank and a second bank,
the switch circuit is commonly electrically connected to the first bank and the second bank, and
for reading data held in the memory cell array by outputting the data to the interface, the controller is configured to select the first bank and the second bank alternately, and thereby to input the clock into the first bank and the second bank in turn.

12. The memory system of claim 5, wherein
the plurality of banks include a first bank and a second bank,
the switch circuit is commonly electrically connected to the first bank and the second bank, and
for reading data held in the memory cell array by outputting the data to the interface, the controller is configured to select the first bank and the second bank alternately, and thereby to input the clock into the first bank and the second bank in turn.

13. The memory system of claim 8, wherein
the plurality of banks include a first bank and a second bank,
the switch circuit is commonly electrically connected to the first bank and the second bank, and
for reading data held in the memory cell array by outputting the data to the interface, the controller is configured to select the first bank and the second bank alternately, and thereby to input the clock into the first bank and the second bank in turn.

14. The memory system of claim 9, wherein
the plurality of banks include a first bank and a second bank,
the switch circuit is commonly electrically connected to the first bank and the second bank, and
for reading data held in the memory cell array by outputting the data to the interface, the controller is configured to select the first bank and the second bank alternately, and thereby to input the clock into the first bank and the second bank in turn.

15. The memory system of claim 4, wherein
the plurality of banks include a first bank, a second bank, a third bank and a fourth bank,
the switch circuit includes a first switch circuit and a second switch circuit,
the first switch circuit is commonly electrically connected to the first bank and the second bank,
the second switch circuit is commonly electrically connected to the third bank and the fourth bank, and
the controller alternately selects the first switch circuit and the second switch circuit, and thereby alternately switches between an electrical connection between the buffer circuit and any one of the first bank and the second bank, and an electrical connection between the buffer circuit and any one of the third bank and the fourth bank.

16. The memory system of claim 5, wherein
the plurality of banks include a first bank, a second bank, a third bank and a fourth bank,
the switch circuit includes a first switch circuit and a second switch circuit,
the first switch circuit is commonly electrically connected to the first bank and the second bank,
the second switch circuit is commonly electrically connected to the third bank and the fourth bank, and
the controller alternately selects the first switch circuit and the second switch circuit, and thereby alternately switches between an electrical connection between the buffer circuit and any one of the first bank and the second bank, and an electrical connection between the buffer circuit and any one of the third bank and the fourth bank.
